(19) United States
(12) Patent Application Publication
(10) Pub. No.: US 2023/0201961 A1
(43) Pub. Date: Jun. 29, 2023

(54) SURFACE PROCESSING MACHINE

(71) Applicant: DISCO CORPORATION, Tokyo (JP)

(72) Inventor: Keiji NOMARU, Tokyo (JP)

(21) Appl. No.: 18/068,661

(22) Filed: Dec. 20, 2022

(30) Foreign Application Priority Data
Dec. 24, 2021 (JP) 2021-211214

(51) Int. Cl. B23K 26/06; B23K 26/067; B23K 26/352; B23K 26/70; B23K 26/03; B23K 26/08

(52) U.S. Cl. CPC B23K 26/0648; B23K 26/0676; B23K 26/352; B23K 26/702; B23K 26/03; B23K 26/0823; B23K 2101/40

(57) ABSTRACT

A surface processing machine for processing a surface of a workpiece has a processing unit which includes a laser oscillator that emits a laser beam, a condenser that forms the laser beam which has been emitted by the laser oscillator, into a plurality of beams, a collimation lens that is arranged between the laser oscillator and the condenser and collimates the laser beam into parallel light, a beam intensity adjuster that is arranged between the condenser and the collimation lens and adjusts an intensity of the beams, and a rotating mechanism that rotates the condenser.

### BACKGROUND OF THE INVENTION

### Field of the Invention

The present invention relates to a surface processing machine for processing a surface of a workpiece.

### Description of the Related Art

A wafer with a plurality of devices such as integrated circuits (ICs) or large-scale integration (LSI) circuits formed on a surface thereof and separated by intersecting lines is ground at a back surface thereof by a grinding machine to a desired thickness, and is then divided into individual device chips by a dicing machine or a laser processing machine. The divided device chips are used in electronic equipment such as mobile phones or personal computers.

The grinding machine is constructed including a chuck table that holds the wafer, a grinding unit that supports in a rotatable manner grinding stones to grind the wafer held on the chuck table, and a grinding feed mechanism that brings the grinding unit proximate to the wafer and brings the grinding stones into contact with an upper surface of the wafer, so that the wafer can be processed to the desired thickness (see, for example, JP 2000-288881A).

### SUMMARY OF THE INVENTION

The grinding processing by the above-described grinding machine is allowed to proceed by pressing the to-be-processed surface of the wafer with the rotating grinding stones and causing microfractures. Hence, there is a problem that a plurality of arcuate grinding marks are left on the processed surface and the divided chips are reduced in flexural strength.

In addition, the finish thickness of the wafer depends on the clearance between the chuck table with the wafer held thereon and the grinding stones. The clearance, however, does not remain constant due to wear of the grinding stones and insufficient mechanical rigidity of the grinding unit disposed in the grinding machine. Accordingly, there is another problem that it is relatively difficult to grind the wafer to a uniform thickness over the entirety thereof. Moreover, there is a further problem that, if the thickness of the wafer becomes non-uniform, it is difficult to make an adjustment to provide the wafer with a uniform thickness by partly grinding the wafer with use of the above-described grinding machine.

The present invention therefore has as an object thereof the provision of a surface processing machine which can finish a wafer with a uniform thickness without causing reduction in flexural strength.

In accordance with an aspect of the present invention, there is provided a surface processing machine for processing a surface of a workpiece. The surface processing machine includes a chuck table that holds the workpiece, a processing unit that processes the surface of the workpiece held on the chuck table, and a processing feed mechanism that carries out relative processing feed of the chuck table and the processing unit. The processing unit includes a laser oscillator that emits a laser beam, a condenser that forms the laser beam which has been emitted by the laser oscillator, into a plurality of laser beams, a collimation lens that is arranged between the laser oscillator and the condenser and collimates the laser beam into parallel light, a beam intensity adjuster that is arranged between the condenser and the collimation lens and adjusts an intensity of the laser beams, and a rotating mechanism that rotates the condenser.

Preferably, the condenser may be a microlens array or a diffractive optical element. Preferably, the beam intensity adjuster may be configured to adjust a spatial intensity distribution of the laser beams. Preferably, the processing unit may be configured to apply ablation processing to the surface of the workpiece by positioning focal points of the laser beams on the surface through the condenser before processing the surface.

Preferably, the processing unit may further include a liquid reservoir receptacle arranged between the condenser and the workpiece and configured to submerge the surface of the workpiece in liquid. Preferably, the processing unit may be configured to apply processing to the surface of the workpiece with plasma generated by application of the laser beams to the liquid in which the surface of the workpiece is submerged in the liquid reservoir receptacle, or the processing unit may be configured to apply processing to the surface of the workpiece with cavitation occurred by application of the laser beams to the liquid in which the surface of the workpiece is submerged in the liquid reservoir receptacle. Preferably, the processing unit may further include a gauge that measures one of a thickness or a height of the workpiece held on the chuck table.

According to the present invention, it is possible to avoid a plurality of arcuate grinding marks otherwise being formed and remaining on the ground surface if the workpiece is processed by grinding machine of the related art, and hence to suppress the problem of reduction in flexural strength. Further, since the finish thickness of the workpiece does not depend on the clearance between the chuck table and the grinding stones unlike the grinding machine of the related art, formation of the workpiece processed to a uniform thickness is easily realized.

The above and other objects, features and advantages of the present invention and the manner of realizing them will become more apparent, and the invention itself will best be understood from a study of the following description and appended claims with reference to the attached drawings showing some preferred embodiments of the invention.

### BRIEF DESCRIPTION OF THE DRAWINGS

FIG. 1 is a perspective view illustrating a bonding step of a protective tape to a front surface of a wafer as a workpiece to be processed by a surface processing machine of the present invention;

FIG. 2 is an overall perspective view of a surface processing machine of a first embodiment of the present invention;

FIG. 3 is a partly cross-sectional side view illustrating an optical system of a processing unit disposed in the surface processing machine of FIG. 2 and partly illustrated in cross-section, along with how surface processing is performed by the processing unit;

FIG. 4 is a fragmentary perspective view illustrating the surface processing of FIG. 3 in further detail;

FIG. 5 is an overall perspective view of a surface processing machine of a second embodiment of the present invention;

FIG. 6 is a fragmentary perspective view illustrating how surface processing is performed by the processing unit partly illustrated in cross-section and a liquid reservoir receptacle, both of which are disposed in the surface processing machine of FIG. 5; and

FIG. 7 is a fragmentary cross-sectional side view illustrating the surface processing of FIG. 6 in further detail.

### DETAILED DESCRIPTION OF THE PREFERRED EMBODIMENTS

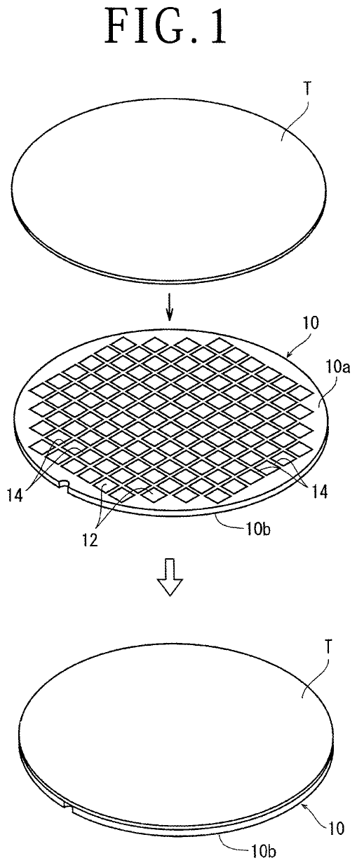

With reference to FIGS. 1 through 4 of the attached drawings, a description will hereinafter be made in detail with regard to a surface processing machine 1 of a first embodiment of the present invention.

FIG. 1 is a perspective view illustrating a bonding step of a protective tape T to a front surface 10a of a wafer 10 as a workpiece to be processed by a surface processing machine of the present invention. The wafer 10 is made, for example, from silicon (Si), and includes, for example, a plurality of devices 12 formed separated by a plurality of intersecting streets 14 on the front surface 10a. On the front surface 10a of the wafer 10, the protective tape T is bonded, and as illustrated in a lower part of FIG. 1, the protective tape T is integrated with the wafer 10 and protects the front surface 10a when the wafer 10 is processed at a back surface 10b thereof by the surface processing machine 1 as will be described subsequently herein.

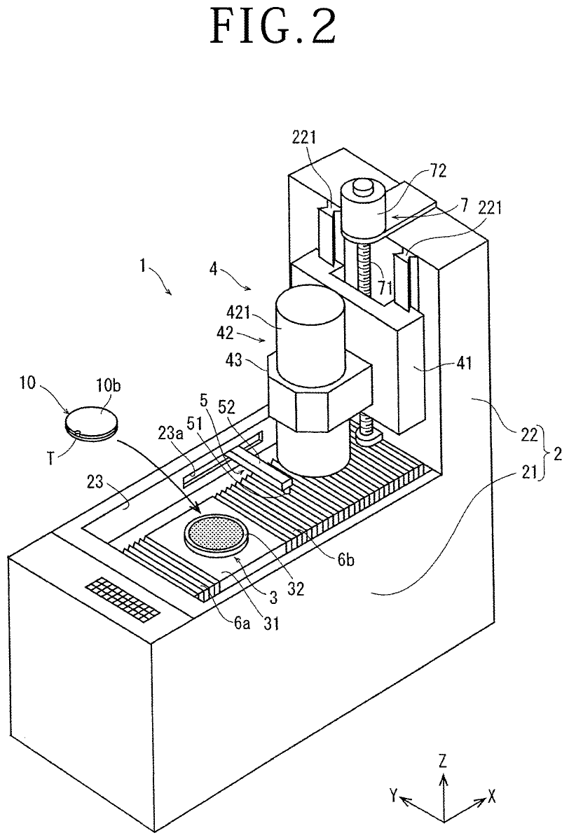

FIG. 2 is an overall perspective view of the surface processing machine 1 of the first embodiment of the present invention. The surface processing machine 1 includes a machine housing 2, which has a substantially parallelepiped main body section 21 and an upright wall 22 arranged on a rear end portion of the main body section 21 and disposed upright in an up-and-down direction. The surface processing machine 1 includes a holding unit 3 and a processing unit 4. The holding unit 3 includes a chuck table 32, which is disposed on a cover member 31 arranged above the main body section 21 and holds the wafer 10 by suction. The processing unit 4 processes the back surface 10b of the wafer 10 held on the holding unit 3.

On opposite sides in an X-axis direction, which is indicated by an arrow X in the figure, of the cover member 31, bellows 6a and 6b are disposed. Inside the main body section 21, a processing feed mechanism (not illustrated) is disposed to carry out processing feed of the chuck table 32 of the holding unit 3 in the X-axis direction. Operation of the processing feed mechanism moves the cover member 31 along with the chuck table 32 in the X-axis direction to allow the bellows 6a and 6b to expand and contract or to contract and expand, respectively, whereby the unprocessed wafer 10 can be moved between a loading/unloading region on a nearer side in the figure, where the unprocessed wafer 10 is placed on the chuck table 32, and a processing region on a farther side in the figure, where processing is applied to the unprocessed wafer 10 by the processing unit 4.

The processing unit 4 includes a laser applying unit 42. The laser applying unit 42 includes an optical system accommodated in a processing unit housing 421. The laser applying unit 42 is arranged on a forward side of the upright wall 22, and is mounted on a movable base 41 via a support member 43. The movable base 41 is, on a side of a rearward surface thereof, in engagement with a pair of guide rails 221 disposed on the upright wall 22 of the machine housing 2, and is mounted slidably relative to the guide rails 221 in a Z-axis direction (the up-and-down direction).

The surface processing machine 1 illustrated in FIG. 2 includes a Z-axis moving mechanism 7, which moves the processing unit 4 along the paired guide rails 221 in a direction indicated by an arrow Z in the figure. The Z-axis moving mechanism 7 includes an externally threaded rod 71, which is disposed on the side of the forward surface of the upright wall 22 and extends in the up-and-down direction. The externally threaded rod 71 is rotatably supported at an upper end portion and lower end portion thereof on the upright wall 22. Disposed on the upper end portion of the externally threaded rod 71 is a pulse motor 72 as a drive source for rotationally driving the externally threaded rod 71, and the pulse motor 72 is connected at an output shaft thereof to the externally threaded rod 71. On the rearward surface of the movable base 41, a threaded connection portion (not illustrated) is formed, and through the connection portion, an internal screw hole is formed extending in the up-and-down direction. The externally threaded rod 71 is in threaded engagement with the internal screw hole. The Z-axis moving mechanism 7 of the above-described configuration can lower the processing unit 4 along with the movable base 41 by normally rotating the pulse motor 72, and can raise the processing unit 4 along with the movable base 41 by reversely rotating the pulse motor 72.

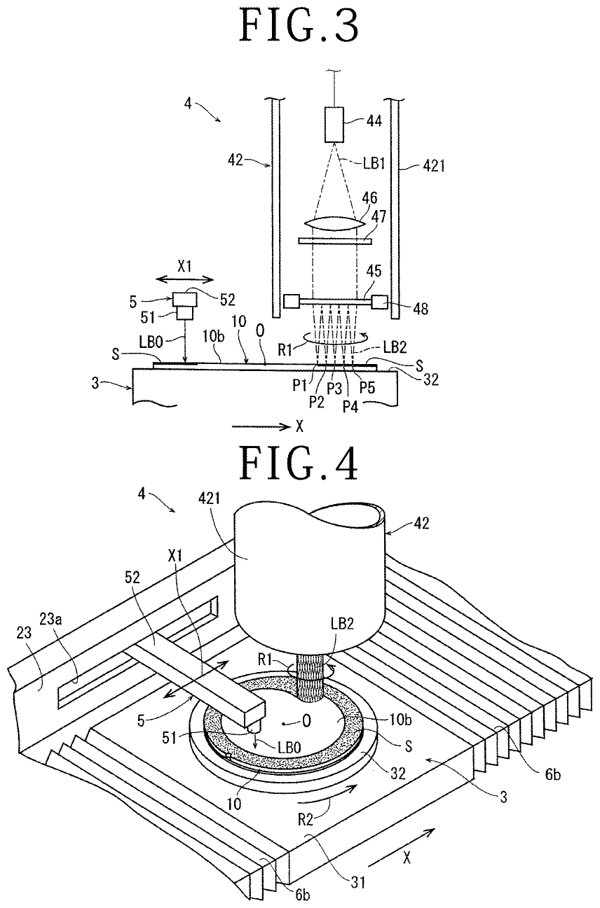

In the surface processing machine 1 of this embodiment, a gauge 5 is disposed to measure the thickness (or height) of the wafer 10 held on the chuck table 32 of the holding unit 3. The gauge 5 is arranged, on the main body section 21 of the machine housing 2, at a position approximate in a Y-axis direction to the chuck table 32 in a region in which the chuck table 32 moves in the X-axis direction, and is disposed on a side wall portion 23 formed along the X-axis direction. Further, the gauge 5 is configured to be driven by a moving mechanism (not illustrated) disposed inside the side wall portion 23, and to be movable along a slide groove 23a in the side wall portion 23. The slide groove 23a is formed along a direction indicated by an arrow X1 (see FIGS. 3 and 4). No particular limitation is imposed on the type of the gauge 5. For example, the gauge 5 is a contactless thickness gauge, which measures the thickness (or height) of the wafer 10 by applying a measuring laser beam LB0 (see FIGS. 3 and 4) of a predetermined wavelength range from a distal end portion 51 of an extension arm 52, detecting return light reflected by the back surface 10b and the front surface 10a of the wafer 10, and then performing a Fourier transform of a spectral interference waveform based on the return light. The above-described laser applying unit 42, processing feed mechanism (not illustrated), gauge 5, Z-axis moving mechanism, and the like are connected to a controller (not illustrated).

FIG. 3 is a partly cross-sectional side view illustrating an optical system of the processing unit 4 disposed in the surface processing machine 1 of FIG. 2 and partly illustrated in cross-section, along with how surface processing is performed by the processing unit 4. Described with reference to FIG. 3 in addition to FIG. 2, the optical system of the laser applying unit 42, which constitutes the processing unit 4 in this embodiment, will be described more specifically. The laser applying unit 42 is configured including a laser oscillator 44 that emits a laser beam LB1, a condenser 45 that forms the laser beam LB1 which has been emitted by the laser oscillator 44, into a plurality of beams LB2, a collimation lens 46 that is disposed between the laser oscillator 44 and the condenser 45 and collimates the laser beam LB1 into parallel light, a beam intensity adjuster 47 that is disposed between the condenser 45 and the collimation lens 46 and adjusts an intensity of the beams LB2, and a rotating mechanism 48 that rotates the condenser 45 to rotate the beams LB2 in a direction indicated by an arrow R1. The above-described optical system of the laser applying unit 42 is accommodated in the processing unit housing 421 supported by the support member 43.

As the condenser 45, it is possible to use, for example, a microlens array that is an optical lens with a plurality of microlenses of micrometer order size arranged in succession or a diffractive optical element (DOE) that spatially splits a laser beam with use of the diffraction phenomenon of light. According to the laser applying unit 42, through the condenser 45, the laser beam LB1 emitted from the laser oscillator 44 can be formed into the beams LB2 which can then be applied while being dispersed and focused over a predetermined irradiation region (see focal points P1 to P5 in the figure). It is to be noted that, in FIG. 3, the focal points of the beams LB2 formed at the condenser 45 are simplified and indicated as P1 to P5 for the convenience of explanation. In practice, however, the beams LB2 are dispersed into a desired number of a plurality of beams, for example, approximately several hundreds of beams in the range of the predetermined irradiation region. The condenser 45 is not limited to the configuration of the above-described microlens array or diffraction optical element alone, and may also be configured by combination with one or more additional condenser lenses, aspherical lenses, or the like.

As the rotating mechanism 48, a hollow motor is adopted, for example. The hollow motor includes encoders arranged on an outer periphery of a hollow shaft, and is formed in an annular shape. With being held in a central space of the shaft, the condenser 45 is rotated at a high speed (for example, 50000 rpm or lower), and the beams LB2 applied from the condenser 45 can be rotated in the direction indicated by the arrow R1.

As the beam intensity adjuster 47, a spatial light modulator (reflective type (liquid crystal on silicon (LCOS)) or transmissive type (liquid crystal display (LCD))) or a digital micromirror device (DMD) can be used. The laser beam LB1 passed through the collimation lens 46 is adjusted by the beam intensity adjuster 47, so that the spatial strength distribution of the beams LB2 to be applied from the condenser 45 can be adjusted to a desired spatial strength distribution. In this embodiment, an example with an LCOS, i.e., reflective spatial light modulator, adopted therein is illustrated. However, an LCD, i.e., transmissive spatial light modulator, can also be adopted.

As illustrated in FIG. 3, the laser applying unit 42 of this embodiment applies ablation processing to the back surface 10b of the wafer 10 by applying the beams LB2 from the condenser 45 with their focal points (for example, P1 to P5) positioned on the back surface 10b of the wafer 10. When surface processing is performed by the laser applying unit 42 in this embodiment, processing conditions can be set, for example, as follows.

Wavelength: 355 nm

Pulse width: 10 ps

Repetition frequency: 1 MHz

Average output power: 10 W

Numerical aperture (NA): 0.2

A description will be made more specifically with regard to procedures that can be followed to process the back surface 10b of the wafer 10 by the above-described surface processing machine 1.

As illustrated in FIG. 2, after the holding unit 3 has been positioned in the loading/unloading region, the side of the back surface 10b of the wafer 10 which is integrated with the protective tape T is directed upward, and the wafer 10 is placed on a side of the protective tape T on the chuck table 32 and is held by suction. The processing feed mechanism (not illustrated) is then operated to move the chuck table 32 in the X-axis direction to a side of the processing region, so that an outer peripheral edge of the wafer 10 is positioned at a location where the beams LB2 are applied from the condenser 45 of the processing unit 4.

FIG. 4 is a fragmentary perspective view illustrating the surface processing of FIG. 3 in further detail. The above-described laser oscillator 44, beam intensity adjuster 47, rotating mechanism 48, and Z-axis moving mechanism 7 are next operated, whereby, as illustrated in FIGS. 3 and 4, the beams LB2 are applied from the laser applying unit 42 with their focal points (P1 to P5) positioned on the back surface 10b of the wafer 10, the beams LB2 are rotated in the direction indicated by the arrow R1, and the chuck table 32 is moved in the X-axis direction while being rotated in a direction indicated by an arrow R2. The surface processing is performed until the beams LB2 reach a center O of the wafer 10.

By application of the ablation processing to the back surface 10b of the wafer 10 through the above-described surface processing, a region S on the back surface 10b, to which the beams LB2 have been applied, gradually spreads, and the thickness of the wafer 10 decreases. The gauge 5 is disposed in the surface processing machine 1 of this embodiment as described above. The extension arm 52 of the gauge 5 is moved in the direction indicated by the arrow X1 along the slide groove 23a of the side wall portion 23 to position the distal end portion 51 above a predetermined position apart from the center O of the wafer 10, and the measuring laser beam LB0 is then applied. The gauge 5 measures the thickness of the wafer 10 at the predetermined position by detecting return light of the measuring laser beam LB0 reflected by the back surface 10b and the front surface 10a of the wafer 10, and then performing a Fourier transform of a spectral interference waveform based on the return light. Such measurement is performed at a plurality of positions defined by X coordinates and Y coordinates on the wafer 10 while the extension arm 52 is moved and the chuck table 32 is rotated, whereby the thickness of the wafer 10 is measured in detail over the entire area of the wafer 10.

When the thickness of the wafer 10 is measured by the gauge 5, the surface processing by the laser applying unit 42 is preferably stopped. The controller (not illustrated) first determines whether or not the thickness of the wafer 10 as detected by the measurement has reached the desired thickness. If the desired thickness has not been reached yet, the surface processing of the wafer 10 by the laser applying unit 42 is resumed, and is continued until the desired thickness is reached. Further, rinsing water ejection means may be disposed to eject high-pressure rinsing water to the region to which the measuring laser beam LB0 is applied from the gauge 5, and the above-described thickness measurement may be performed while the wafer 10 in the region where the thickness is to be measured is rinsed.

According to this embodiment, the beams LB2 to be applied from the condenser 45 are rotated by the rotating mechanism 48 in the direction indicated by the arrow R1, and the wafer 10 is rotated along with the chuck table 32 in the direction indicated by the arrow R2. As a consequence, the back surface 10b of the wafer 10 is progressively and uniformly removed in the region to which the beams LB2 have been applied. It is therefore possible to avoid a plurality of arcuate grinding marks otherwise being formed and remaining on the ground surface if the workpiece is processed by grinding machine of the related art, and hence to suppress the problem of reduction in flexural strength. Further, since the finish thickness of the wafer 10 does not depend on the clearance between the chuck table and the grinding stones unlike the grinding machine of the related art as described above, formation of the wafer 10 processed to a uniform thickness is easily realized. Owing to the inclusion of such a configuration as described above, the surface (back surface 10b) of the wafer 10 can be processed into a desired shape by processing the surface of the wafer 10 in parts while the chuck table 32 is moved, the beams LB2 are positioned at desired positions on the wafer 10, the movement of the chuck table 32 is stopped, the rotation of the condenser 45 is stopped, and other operations are performed as needed.

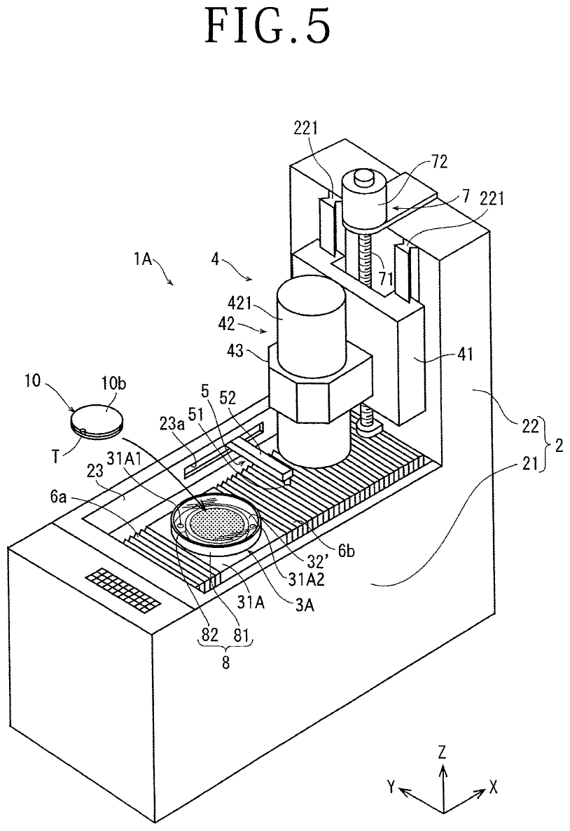

The present invention is not limited to the above-described surface processing machine 1 of the first embodiment. With reference to FIGS. 5 to 7, a surface processing machine 1A of a second embodiment of the present invention will be described next.

FIG. 5 is an overall perspective view of the surface processing machine 1A of the second embodiment of the present invention. The surface processing machine 1A has substantially the same configuration as the above-described surface processing machine 1, common elements are identified by the same reference numerals, and their detailed descriptions are omitted.

As illustrated in FIG. 5, the surface processing machine 1A of the second embodiment includes a liquid reservoir receptacle 8 in addition to the surface processing machine 1 of the first embodiment. The liquid reservoir receptacle 8 is, for example, a recessed container having an opening on a lower side thereof, and includes a cylindrical frame member 81 and a transparent plate member 82 that closes the frame member 81 on a side of an upper end edge thereof and allows transmission of the beams LB2 applied from the condenser 45 of the laser applying unit 42. As the plate member 82, a glass plate, an acrylic plate, or the like can be adopted, for example. The liquid reservoir receptacle 8 is detachably disposed on a cover member 31A of a holding unit 3A. With the wafer 10 placed in a suction-held state on a chuck table 32A, the liquid reservoir receptacle 8 is disposed between the condenser 45 and the wafer 10 held on the chuck table 32A.

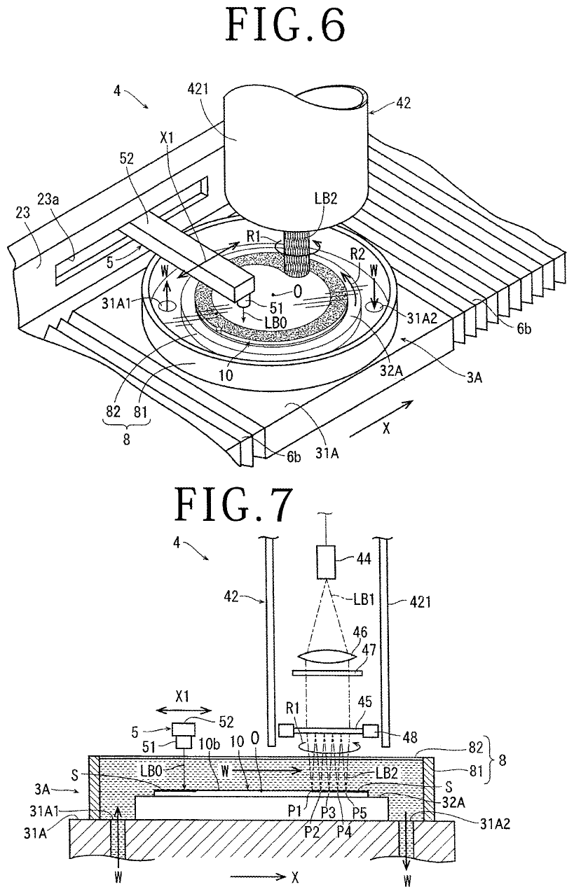

FIG. 6 is a fragmentary perspective view illustrating how surface processing is performed by the processing unit 4 partly illustrated in cross-section and the liquid reservoir receptacle 8, both of which are disposed in the surface processing machine 1A of FIG. 5, and FIG. 7 is a fragmentary cross-sectional side view illustrating the surface processing of FIG. 6 in further detail. As illustrated in FIGS. 6 and 7, the cover member 31A includes a liquid supply port 31A1 that supplies liquid W (for example, pure water) to be held in the liquid reservoir receptacle 8, and a liquid drain port 31A2 that drains the liquid W. The liquid W is supplied under pressure from liquid supply means (not illustrated), is supplied from the liquid supply port 31A1 into the liquid reservoir receptacle 8, fills an interior of the liquid reservoir receptacle 8, and is drained from the liquid drain port 31A2 as needed. It is to be noted that the liquid supply port 31A1 and the liquid drain port 31A2 are not absolutely limited to being disposed through the cover member 31A, and may be arranged, for example, through a side surface of the frame member 81 of the liquid storage receptacle 8. Further, close contact is not necessarily required between the liquid reservoir receptacle 8 and the cover member 31A, and an appropriate clearance may be formed between the liquid reservoir receptacle 8 and the cover member 31A to drain the liquid W through the clearance.

The surface processing machine 1A of the second embodiment performs surface processing through substantially the same procedures as the above-described surface processing machine 1 of the first embodiment. Described more specifically, with the holding unit 3A positioned in the loading/unloading region, the wafer 10 integrated with the protective tape T bonded to the front surface 10a is placed and held, on the side of the protective tape T, by suction on the chuck table 32A, with the side of the back surface 10b directed upward, before the liquid reservoir receptacle 8 is mounted on the cover member 31A. Next, the liquid reservoir receptacle 8 is mounted on the cover member 31A, and the liquid W is supplied from the liquid supply port 31A1 to fill the interior of the liquid reservoir receptacle 8 with the liquid W. The processing feed mechanism (not illustrated) is then operated to move the chuck table 32A in the X-axis direction to the side of the processing region, so that the outer peripheral edge of the wafer 10 is positioned at the location where the beams LB2 are applied from the condenser 45 of the laser applying unit 42, and the liquid reservoir receptacle 8 is disposed between the condenser 45 and the wafer 10.

The above-described laser oscillator 44, beam intensity adjuster 47, rotating mechanism 48, and Z-axis moving mechanism 7 are next operated, whereby, as illustrated in FIGS. 6 and 7, the beams LB2 are applied from the laser applying unit 42 with their focal points (P1 to P5) positioned on the back surface 10b of the wafer 10, and are rotated in the direction indicated by the arrow R1, and the chuck table 32A is moved in the X-axis direction while being rotated in the direction indicated by the arrow R2. The surface processing is performed until the beams LB2 reach the center O of the wafer 10. During this time, the liquid W is supplied from the liquid supply port 31A1 into the liquid reservoir receptacle 8, and is drained from the liquid drain port 31A2. As a consequence, processing debris and the like, which occur by the processing performed by the surface processing, are eliminated with the liquid W.

By application of the ablation processing to the back surface 10b of the wafer 10 through the above-described surface processing, the region S on the back surface 10b, to which the beams LB2 have been applied, gradually spreads, and the thickness of the wafer 10 decreases. As the liquid reservoir receptacle 8 is disposed in the surface processing machine 1A of the second embodiment, the measurement of the thickness of the wafer 10 by the gauge 5 is preferably performed after the liquid reservoir receptacle 8 is detached. By the gauge 5, the thickness of the wafer 10 is measured at a plurality of positions defined by X coordinates and Y coordinates on the wafer 10, whereby the thickness of the wafer 10 is measured in detail over the entire area of the wafer 10. The controller (not illustrated) first determines whether or not the thickness of the wafer 10 as detected by the measurement has reached the desired thickness. If the desired thickness has not been reached yet, the liquid reservoir receptacle 8 is mounted again, and the processing of the wafer 10 by the laser applying unit 42 is resumed, and is continued until the desired thickness is reached.

By submerging the to-be-processed back surface 10b of the wafer 10 in the liquid W with use of the liquid reservoir receptacle 8, it is possible, as described above, not only to swiftly eliminate processing debris and the like occurred by the processing but also to realize such processing as will be described below.

In the above-described surface processing, the application of ablation processing is ensured with the focal points (P1 to P5) of the beams LB2 positioned on the back surface 10b of the wafer 10. It is also possible to apply the beams LB2, for example, with the focal points (P1 to P5) made slightly apart (for example, less than 1 mm, preferably 0.5 mm) from the back surface 10b of the wafer 10. In this manner, the liquid W is plasmatized in a vicinity of the back surface 10b of the wafer 10, so that plasma processing is also applied to the back surface 10b in addition to application of the above-described ablation processing. As a consequence, combined processing is applied to the back surface 10b, and hence more uniform processing can be applied. In addition, with the focal points (P1 to P5) of the beams LB2 made apart (for example, 1 mm or more, preferably 1 mm) from the back surface 10b of the wafer 10, cavitation is allowed to occur in vicinities of the focal points, so that the back surface 10b can also be processed by shock waves generated upon collapse of cavitation bubbles.

By the above-described surface processing machine 1A of the second embodiment, it is also possible to obtain advantageous effects similar to those available from the surface processing machine 1 of the first embodiment described previously. In addition, the surface processing machine 1A of the second embodiment can also plasmatize the liquid W in the vicinity of the back surface 10b of the wafer 10 to perform surface processing with the resulting plasma and/or can also allow cavitation to occur in the vicinity of the back surface 10b to perform surface processing by shock waves generated upon collapse of cavitation bubbles, so that the back surface 10b can processed more uniformly.

The above-described ablation processing, plasma processing, and cavitation processing are preferably applied in combination to the back surface 10b of the wafer 10 instead of selective application of one of them. For optimal performance of the respective processing by ablation processing, plasma processing, and cavitation processing, however, processing conditions (the positions of focal points, average output power, etc., of the beams LB2) are different. It is therefore preferred to determine beforehand, by a simulation, an experiment, or the like, optimal processing conditions for processing the wafer 10 to a more uniform thickness.

The present invention is not limited to the details of the above described preferred embodiments. The scope of the invention is defined by the appended claims and all changes and modifications as fall within the equivalence of the scope of the claims are therefore to be embraced by the invention.

What is claimed is:

1. A surface processing machine for processing a surface of a workpiece, the surface processing machine comprising:
a chuck table that holds the workpiece;
a processing unit that processes the surface of the workpiece held on the chuck table; and
a processing feed mechanism that carries out relative processing feed of the chuck table and the processing unit,
wherein the processing unit includes
a laser oscillator that emits a laser beam,
a condenser that forms the laser beam which has been emitted by the laser oscillator, into a plurality of laser beams,
a collimation lens that is arranged between the laser oscillator and the condenser and collimates the laser beam into parallel light,
a beam intensity adjuster that is arranged between the condenser and the collimation lens and adjusts an intensity of the laser beams, and
a rotating mechanism that rotates the condenser.

2. The surface processing machine according to claim 1, wherein the condenser is a microlens array or a diffractive optical element.

3. The surface processing machine according to claim 1, wherein the beam intensity adjuster is configured to adjust a spatial intensity distribution of the laser beams.

4. The surface processing machine according to claim 1, wherein the processing unit is configured to apply ablation processing to the surface of the workpiece by positioning focal points of the laser beams on the surface through the condenser before processing the surface.

5. The surface processing machine according to claim 1, wherein the processing unit further includes a liquid reservoir receptacle arranged between the condenser and the workpiece and configured to submerge the surface of the workpiece in liquid.

6. The surface processing machine according to claim 5, wherein the processing unit is configured to apply processing to the surface of the workpiece with plasma generated by application of the laser beams to the liquid in which the surface of the workpiece is submerged in the liquid reservoir receptacle.

7. The surface processing machine according to claim 5, wherein the processing unit is configured to apply processing to the surface of the workpiece with cavitation occurred by application of the laser beams to the liquid in which the surface of the workpiece is submerged in the liquid reservoir receptacle.

8. The surface processing machine according to claim 1, wherein the processing unit further includes a gauge that measures one of a thickness or a height of the workpiece held on the chuck table.
